(19) United States
(12) Patent Application Publication
(10) Pub. No.: US 2022/0384306 A1
(43) Pub. Date: Dec. 1, 2022

(54) THERMAL INTERFACE STRUCTURE FOR INTEGRATED CIRCUIT DEVICE ASSEMBLIES

(71) Applicant: Intel Corporation, Santa Clara, CA (US)

(72) Inventors: Weihua Tang, Chandler, AZ (US); Chandra Mohan Jha, Chandler, AZ (US); Nicholas S. Haehn, Scottsdale, AZ (US)

(73) Assignee: Intel Corporation, Santa Clara, CA (US)

(21) Appl. No.: 17/330,870

(22) Filed: May 26, 2021

(51) Int. Cl. H01L 23/433; H01L 23/00

(52) U.S. Cl. CPC H01L 23/433; H01L 24/32; H01L 2224/73253; H01L 2224/16227; H01L 24/16; H01L 24/73

(57) ABSTRACT

A thermal interface structure for facilitating heat transfer from an integrated circuit device to a heat dissipation device may be fabricated to include at least one conductive wire structure wherein each conductive wire structure includes a conductive wire having a first end, a first barrier layer adjacent the first end of the conductive wire, and a first solder structure adjacent the first barrier layer. The thermal interface structure may further include an encapsulation material substantially encapsulating each conductive wire structure and a first solder layer abutting the encapsulation material and abutting the first solder structure of each conductive wire structure.

### TECHNICAL FIELD

Embodiments of the present description generally relate to the field of thermal management for integrated circuit device assemblies, and, more specifically, to a thermal interface structure between an integrated circuit device and a heat dissipation device of the integrated circuit device assembly.

### BACKGROUND

The integrated circuit industry is continually striving to produce ever faster, smaller, and thinner integrated circuit devices for use in various electronic products, including, but not limited to, computer servers and portable products, such as portable computers, electronic tablets, cellular phones, digital cameras, and the like.

As these goals are achieved, the density of power consumption of components within the integrated circuit devices has increased, which, in turn, increases the average junction temperature of the integrated circuit device. If the temperature of the integrated circuit device becomes too high, circuits within the integrated circuit device may be damaged or destroyed. Thus, heat dissipation devices are used to remove heat from the integrated circuit devices. In one example, at least one integrated circuit device may be mounted to a substrate and the heat dissipation device may be thermally attached to the at least one integrated circuit device with a thermal interface material (TIM) that is disposed between the integrated circuit device(s) and the heat dissipation device to form thermal contact therebetween.

The thermal interface material primarily serves two functions: 1) to provide a heat transfer path from the integrated circuit device(s) to the heat dissipation device, and 2) to help absorb stresses in the integrated circuit assembly or package caused by differing thermal expansions between the components therein. With regard to providing a heat transfer path, the thermal efficiency of the thermal interface material is critical to effectively remove heat from the integrated circuit device(s). The thermal interface material may include thermal greases, gap pads, polymers, phase-change materials, and the like. However, these thermal interface materials have relatively low thermal conductivities, for example, in the range of about 2 to 8 W/m*K. Thus, it is necessary to minimize bond line thickness to achieve low thermal resistance. However, as will be understood to those skilled in the art, such thermal interface materials can suffer performance degradation over time due to thermo-mechanical stresses result from temperature cycles during the operation of the integrated circuit assembly and manufacturing processes. Although higher thermal conductivity thermal interface materials, such as solder thermal interface materials, may be used, they generally require relatively high bond line thicknesses, such as between about 150 and 400 microns (depending on stresses during operation) to guarantee performance over time.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit assembly, according to one embodiment of the present description.

FIGS. 2-13 are side cross-sectional views of a process for fabrication a thermal interface structure, according to an embodiment of the present description.

FIG. 14 is a side cross-sectional view of an integrated circuit assembly, according to another embodiment of the present description.

FIGS. 15-21 are side cross-sectional views of a process for fabrication a thermal interface structure, according to a further embodiment of the present description.

FIG. 22 is an electronic system, according to one embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures. as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description facilitate thermal transfer between an integrated circuit device and a heat dissipation device through a thermal interface structure. The thermal interface structure may comprise at least one conductive wire structure wherein each conductive wire structure includes a conductive wire having a first end, a first barrier layer adjacent the first end of the conductive wire, and a first solder structure adjacent the first barrier layer. The thermal interface structure may further include an encapsulation material substantially encapsulating each conductive wire structure and a first solder layer abutting the encapsulation material and abutting the first solder structure of each conductive wire structure.

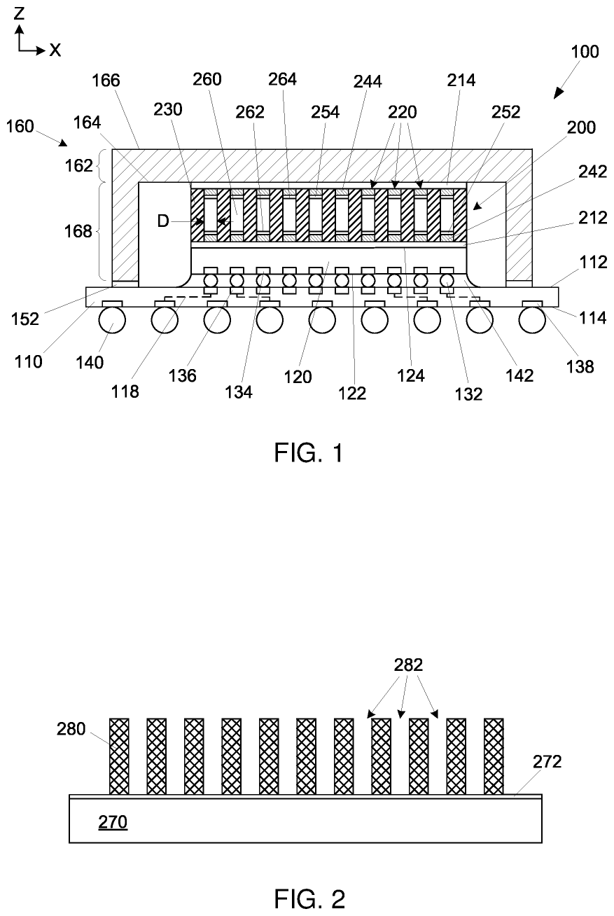

FIG. 1 illustrates an integrated circuit device assembly 100 having at least one integrated circuit device 120 electrically attached to an electronic substrate 110 in a configuration generally known as a flip-chip or controlled collapse chip connection (“C4”) configuration, according to an embodiment of the present description.

The electronic substrate 110 may be any appropriate structure, including, but not limited to, an interposer. The electronic substrate 110 may have a first surface 112 and an opposing second surface 114. The electronic substrate 110 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like.

The electronic substrate 110 may further include conductive routes 118 or “metallization” (shown in dashed lines) extending through the electronic substrate 110. As will be understood to those skilled in the art, the conductive routes 118 may be a combination of conductive traces (not shown) and conductive vias (not shown) extending through the plurality of dielectric material layers (not shown). These conductive traces and conductive vias are well known in the art and are not shown in FIG. 1 for purposes of clarity. The conductive traces and the conductive vias may be made of any appropriate conductive material, including but not limited to, metals, such as copper, silver, nickel, gold, and aluminum, alloys thereof, and the like. As will be understood to those skilled in the art, the electronic substrate 110 may be a cored substrate or a coreless substrate.

The integrated circuit device 120 may be any appropriate device, including, but not limited to, a microprocessor, a chipset, a graphics device, a wireless device, a memory device, an application specific integrated circuit, combinations thereof, stacks thereof, or the like. As shown, the integrated circuit device 120 may have a first surface 122 and the second surface 124.

In an embodiment of the present description, the integrated circuit device 120 may be electrically attached to the electronic substrate 110 with a plurality of device-to-substrate interconnects 132. In one embodiment of the present description, the device-to-substrate interconnects 132 may extend between bond pads 136 on the first surface 112 of the electronic substrate 110 and bond pads 134 on the first surface 122 of the integrated circuit device 120. The device-to-substrate interconnects 132 may be any appropriate electrically conductive material or structure, including, but not limited to, solder balls, metal bumps or pillars, metal filled epoxies, or a combination thereof. In one embodiment, the device-to-substrate interconnects 132 may be solder balls formed from tin, lead/tin alloys (for example, 63% tin/37% lead solder), and high tin content alloys (e.g., 90% or more tin—such as tin/bismuth, eutectic tin/silver, ternary tin/silver/copper, eutectic tin/copper, and similar alloys). In another embodiment, the device-to-substrate interconnects 132 may be copper bumps or pillars. In a further embodiment, the device-to-substrate interconnects 132 may be metal bumps or pillars coated with a solder material.

The bond pads 134 may be in electrical communication with integrated circuitry (not shown) within the integrated circuit device 120. The bond pads 136 on the first surface 112 of the electronic substrate 110 may be in electrical contact with the conductive routes 118. The conductive routes 118 may extend through the electronic substrate 110 and be connected to other integrated circuit devices (not shown) mounted to electronic substrate 110 and/or to bond pads 138 on the second surface 114 of the electronic substrate 110. As will be understood to those skilled in the art, the electronic substrate 110 may reroute a fine pitch (center-to-center distance between the bond pads) of the integrated circuit device bond pads 136 to a relatively wider pitch of the bond pads 138 on the second surface 114 of the electronic substrate 110. In one embodiment of the present description, external interconnects 140 may be disposed on the bond pads 138 on the second surface 114 of the electronic substrate 110. The external interconnects 140 may be any appropriate electrically conductive material, including, but not limited to, metal filled epoxies and solders, such as tin, lead/tin alloys (for example, 63% tin/37% lead solder), and high tin content alloys (e.g., 90% or more tin—such as tin/bismuth, eutectic tin/silver, ternary tin/silver/copper, eutectic tin/copper, and similar alloys). The external interconnects 140 may be used to attach the integrated circuit assembly 100 to an external substrate (not shown), such as a motherboard.

An electrically-insulating underfill material 142, such as an epoxy material, may be disposed between the integrated circuit device 120 and the electronic substrate 110. The underfill material 142 may be used to overcome the mechanical stress issues that can arise from thermal expansion mismatch between the electronic substrate 110 and the integrated circuit device 120. As will be understood to those skilled in the art, the underfill material 142 may be dispensed between the first surface 122 of the integrated circuit device 120 and the first surface 112 of the electronic substrate 110 as a viscous liquid and then hardened with a curing process.

As further shown in FIG. 1, the integrated circuit device assembly 100 may further include a heat dissipation device 160 having a thermal contact surface 164 that is thermally coupled with the second surface 124 of the integrated circuit device 120 with a thermal interface structure 200.

The heat dissipation device 160 may be an integrated heat spreader. In one embodiment of the present description, the heat dissipation device 160 may comprise a main body 162, having the thermal contact surface 164 and an opposing surface 166, and at least one boundary wall 168 extending from the thermal contact surface 164 of the main body 162 of the heat dissipation device 160. The at least one boundary wall 168 may be attached or sealed to the first surface 112 of the electronic substrate 110 with an attachment adhesive or sealant layer 152. The heat dissipation device 160 may be made of any appropriate thermally conductive material, including, but not limited to, at least one metal material and alloys of more than one metal. In a specific embodiment of the present description, the heat dissipation device 160 may comprise copper, nickel, aluminum, alloys thereof, laminated metals including coated materials (such as nickel coated copper), and the like.

As illustrated in FIG. 1, the heat dissipation device 160 may be a single material throughout, such as when the heat dissipation device 160 including the boundary wall 168 is formed by a single process step, including but not limited to, stamping, skiving, molding, and the like. However, embodiments of the present description may also include heat dissipation device 160 made of more than one component. For example, the heat dissipation device boundary wall 168 may be formed separately from the main body 162, then attached together to form the heat dissipation device 160. In one embodiment of the present description, the boundary wall 168 may be a single “picture frame” structure surrounding the integrated circuit device 120.

The attachment adhesive 152 may be any appropriate material, including, but not limited to, silicones (such as polydimethylsiloxane), epoxies, and the like. It is understood that the boundary wall 168 not only secures the heat dissipation device 160 to the electronic substrate 110, but also maintains a desired distance (e.g., bond line thickness) between the thermal contact surface 164 of the heat dissipation device 160 and second surface 124 of the integrated circuit device 120.

Although the heat dissipation device 160 of FIG. 1 is illustrated as an integrated heat spreader, the embodiments of the present description are not so limited, and may be any appropriate configuration. For example, the heat dissipation device 160 may be a heat pipe, a vapor chamber, a liquid cooling device, a cold plate, and the like. When the heat dissipation device 160 is a cold plate, at least one additional thermal management device (not shown) may be attached to an exterior surface 164 of the heat dissipation device 160 to enhance heat removal. Such additional thermal management devices may include, but are not limited to, heat pipes, high surface area dissipation structures with a fan (such as a structure having fins or pillars/columns formed in a thermally conductive structure), liquid cooling devices, and the like.

As illustrated in FIG. 1, the thermal interface structure 200 may comprise a first solder layer 212, wherein the first solder layer 212 abuts the second surface 124 of the integrated circuit device 120. At least one conductive wire structure 220 may be embedded in an encapsulation material 230 and positioned adjacent the first solder layer 212. Each conductive wire structure 220 may comprise a first solder structure 242 adjacent the first solder layer 212, a first barrier layer 252 adjacent the first solder structure 242, a conductive wire 260 having a first end 262 adjacent the first barrier layer 252, and an opposing second end 264, wherein a second barrier layer 254 is adjacent the second end 264 of the conductive wire 260, and a second solder structure 244 adjacent the second barrier layer 254. A second solder layer 214 may be on the encapsulation material 230 adjacent the second solder structure 244 of each conductive wire structure 220, wherein the second solder layer 214 abuts the thermal contact surface 164 of the heat dissipation device 160. In one embodiment, the at least one conductive wire structure 220 may be substantially perpendicular to at least one of the thermal contact surface 164 of the heat dissipation device 160 and the second surface 124 of the integrated circuit device 120.

The first solder layer 212, the second solder layer 214, the first solder structure 242, and the second solder structure 244 may be any appropriate thermally conductive solder material, including but not limited to tin, lead/tin alloys (for example, 63% tin/37% lead solder), high tin content alloys (e.g., 90% or more tin—such as tin/bismuth, eutectic tin/silver, ternary tin/silver/copper, eutectic tin/copper, and similar alloys), indium, indium tin alloys, and the like. In a specific embodiment of the present description, at least one of the first solder layer 212, the second solder layer 214, the first solder structure 242, and the second solder structure 244 may comprise indium.

The encapsulation material 230 may be any appropriate material. In one embodiment of the present description, the encapsulation material 230 may comprise an organic material, such as epoxy. In another embodiment of the present description, the encapsulation material 230 may comprise a thermally conductive material, including, but not limited to, metal filled epoxies, and the like.

The first barrier layer 252 and the second barrier layer 254 may be any appropriate capable of preventing the electromigration of material between the conductive wire 260 and the first solder structure 242, and between the conductive wire 260 and the second solder structure 244, respectively. In one embodiment of the present description, at least one of the first barrier layer 252 and the second barrier layer 254 may comprise a nitride of one or more refractory metals, including, but not limited to titanium nitride, tantalum nitride, titanium zirconium nitride, and the like. In an embodiment of the present description, at least one of the first barrier layer 252 and the second barrier layer 254 may have a thickness of less than about 2 microns.

The conductive wire 260 may be any appropriate conductive material, including, but not limited to, metals and metal alloys, such as copper, aluminum, alloys thereof, and the like. In one embodiment of the present description, the conductive wire structures 220 may each have an average diameter D of between about several hundred nanometers and several hundred micrometers.

FIGS. 2-13 illustrate a process for fabricating the thermal interface structure 200, according to an embodiment of the present description. FIG. 2 illustrates a carrier panel 270, such as a glass panel, coated with a conductive seed material layer 272. The carrier panel 270 may comprise any appropriate substantially rigid material, including but not limited to, glass, ceramic, metal, and the like. In one embodiment, the conductive seed material layer 272 may be made of any appropriate conductive material, including but not limited to, metals, such as copper, silver, nickel, gold, and aluminum, alloys thereof, and the like.

As further shown in FIG. 2, a template structure 280 may be placed or formed on the conductive seed material layer 272. The template structure 280 includes at least one opening 282 extending therethrough, wherein each of the openings 282 exposes a portion of the conductive seed material layer 272. The openings 282 may have any appropriate cross-section (not shown), such as circular, square, triangular, and the like.

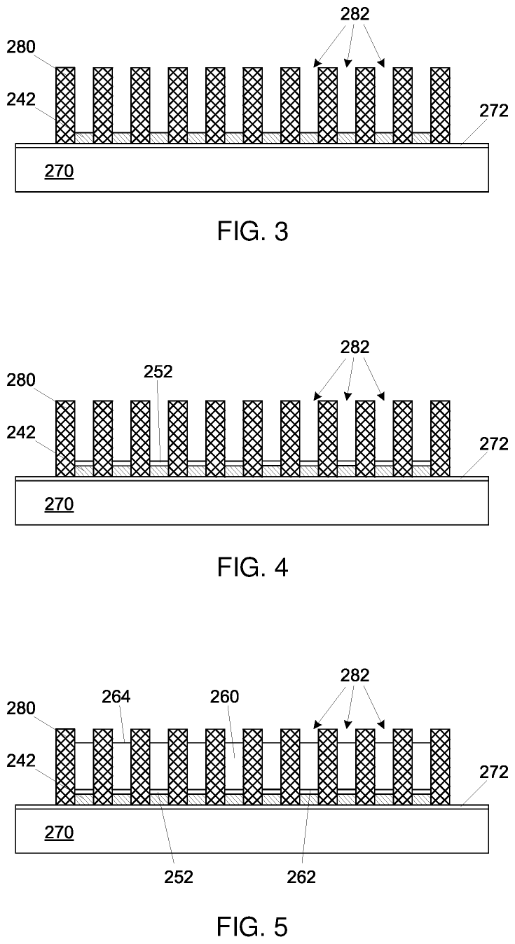

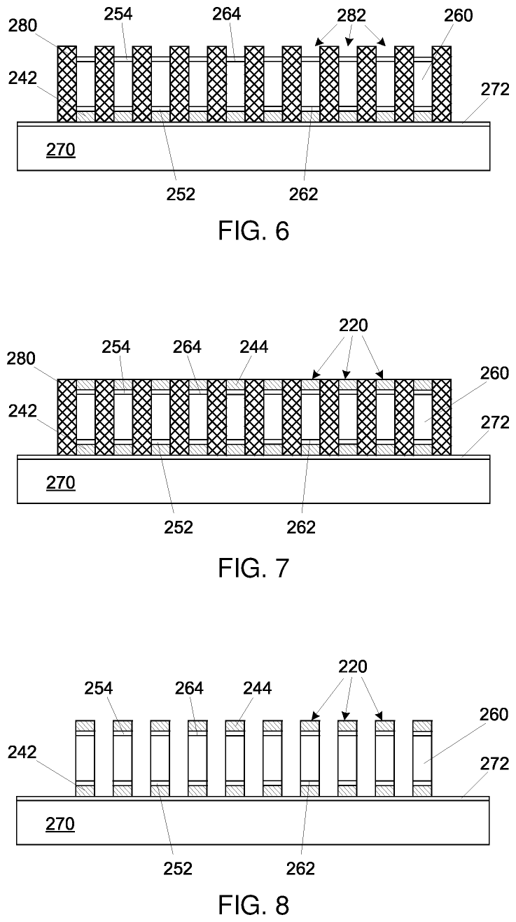

As shown in FIG. 3, the first solder structures 242 may be formed, such as by electroplating, abutting the conductive seed material layer 272 within each opening 282. As shown in FIG. 4, the first barrier layers 252 may be formed, such as by electroplating, adjacent the first solder structures 242 within each opening 282. As shown in FIG. 5, the conductive wires 260 may be formed, such as by electroplating, adjacent the first barrier layers 252 within each opening 282. As shown in FIG. 6, the second barrier layers 254 may be formed, such as by electroplating, adjacent the conductive wires 260 within each opening 282. As shown in FIG. 7, the second solder structures 244 may be formed, such as by electroplating, adjacent the second barrier layers 254 within each opening 282 (see FIG. 6), thereby forming the conductive wire structures 220.

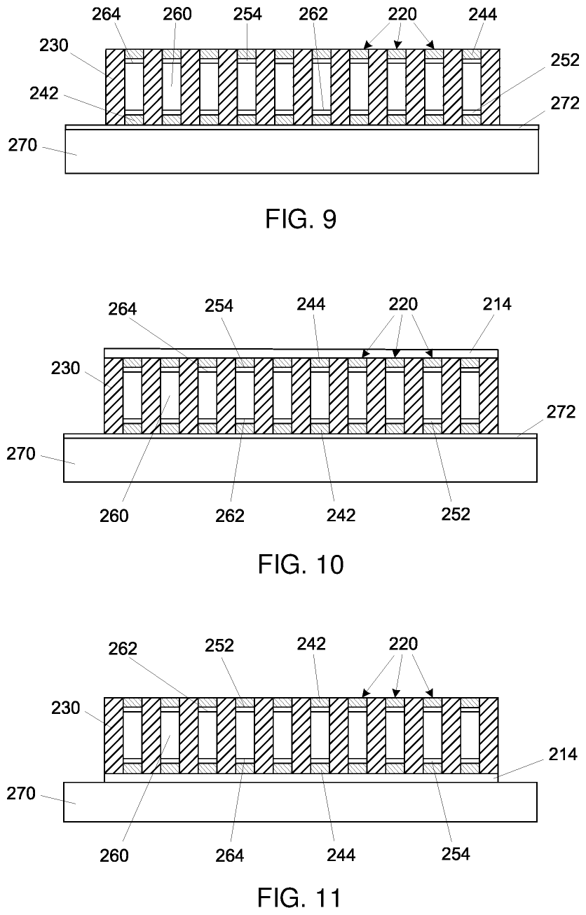

As shown in FIG. 8, the template structure 280 may be removed, such as by chemical dissolution. The encapsulation material 230 may be formed by any appropriate method to substantially encapsulate each of the conductive wire structures 220, with a portion of each of the second solder structures 244 exposed, as shown in FIG. 9. As shown in FIG. 10, the second solder layer 214 may be formed on the encapsulation material 230 and on the second solder structures 244 of each conductive wire structure 220. It is understood that the structure of FIG. 9 may be planarized, such as by grinding, before forming the solder layer 214 on the encapsulation material 230 and on the second solder structures 244.

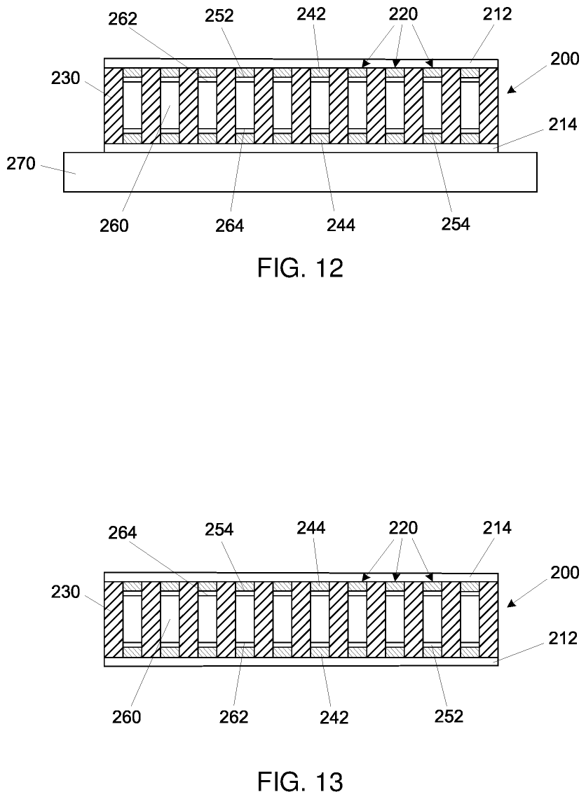

As shown in FIG. 11, the structure of FIG. 10 may be removed from the carrier panel 270, flipped, and reattached by the second solder layer 214 to the carrier panel 270. As shown in FIG. 12, the first solder layer 212 may be formed, such as by electroplating, on the encapsulation material 230 and on the first solder structures 242 of each conductive wire structure 220, thereby forming the thermal interface structure 200. The thermal interface structure 200 may be removed from the carrier 270, as shown in FIG. 13, and incorporated into the integrated circuit device assembly 100, as shown in FIG. 1.

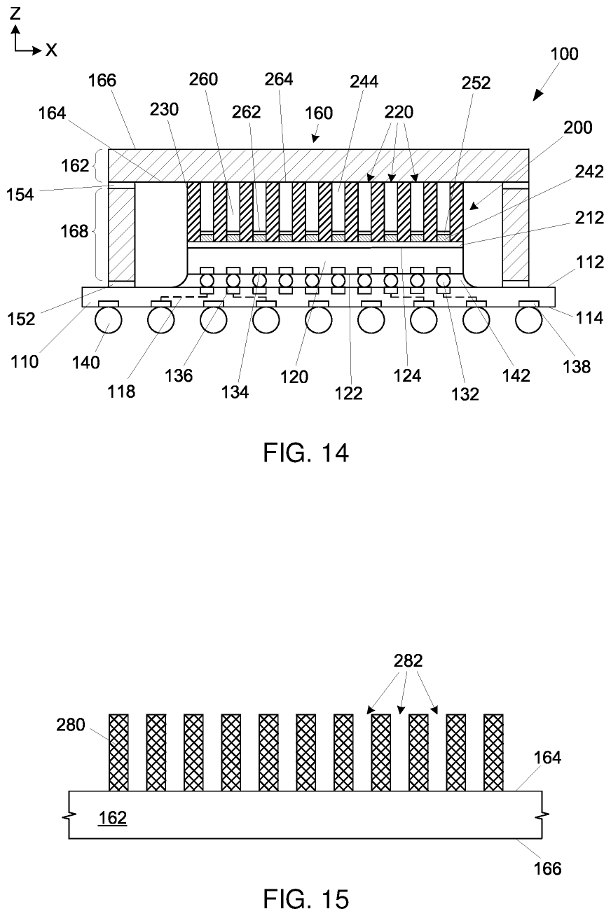

FIG. 14 illustrates another embodiment of an integrated circuit device assembly 100. The illustrated embodiment is similar to the embodiment shown in FIG. 1 with the except of the second ends 264 of the conductive wires 260 of the thermal interface structure 200 directly on the thermal contact surface 164 of the main body 162 of the heat dissipation. Such a configuration allows for the elimination of the second solder layer 214 (see FIG. 1), the second solder structures 244 (see FIG. 1) and the second barrier layer 254 (see FIG. 1). With the embodiment of FIG. 14, the heat dissipation device 160 may comprise two separate components, i.e., the main body 162 and the boundary 168, that are attached with a heat conducting adhesive 154.

FIGS. 15-21 illustrate a process for fabricating the thermal interface structure 200, according to an embodiment of the present description. FIG. 15 illustrates the main body 162 of the heat dissipation device 160 (see FIG. 14) with the template structure 280 may be placed or formed on the thermal contact surface 164 therefore. The template structure 280 includes at least one opening 282 extending therethrough, wherein each opening 282 exposes a portion of the thermal contact surface 164.

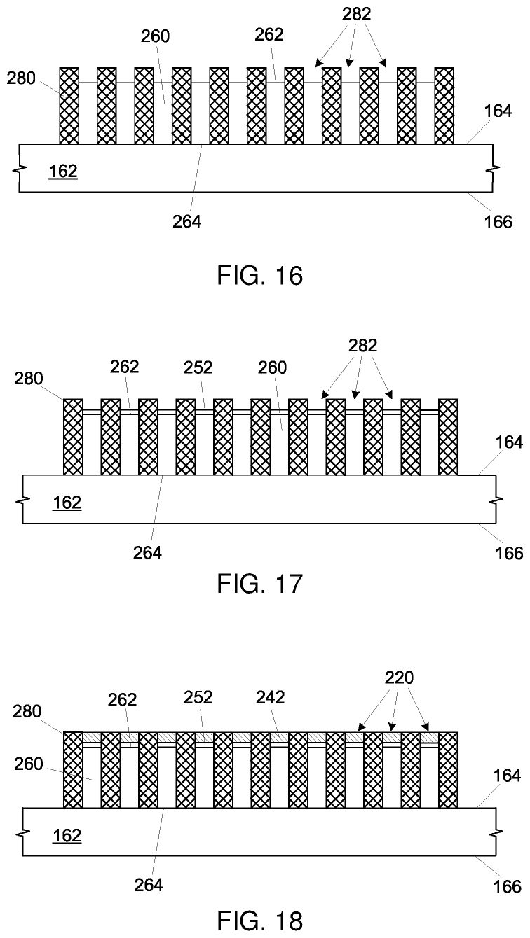

As shown in FIG. 16, the conductive wires 260 may be formed, such as by electroplating, abutting the thermal interface within each opening 282. As shown in FIG. 17, the first barrier layers 252 may be formed, such as by electroplating, adjacent the conductive wires 260 within each opening 282. As shown in FIG. 18, the first solder structures 242 may be formed, such as by electroplating, adjacent the first barrier layers 252 within each opening 282 (see FIG. 17), thereby forming the conductive wire structures 220.

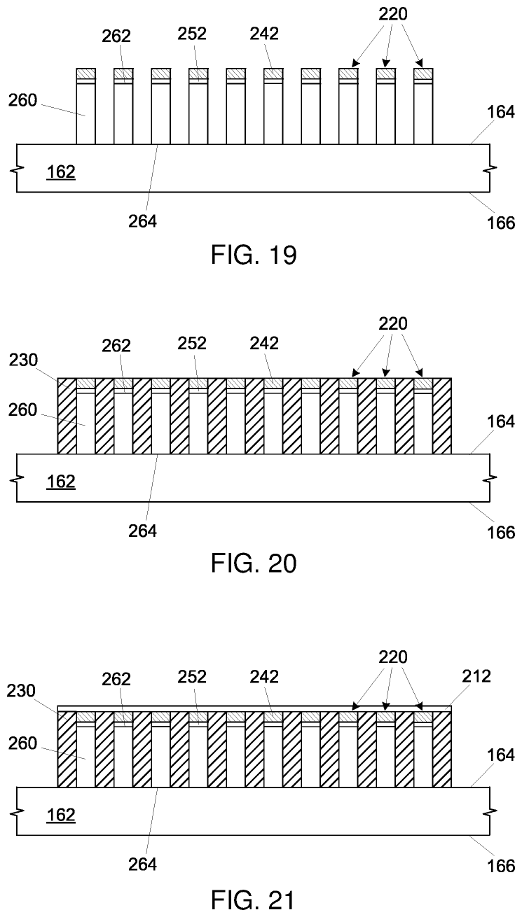

As shown in FIG. 19, the template structure 280 may be removed, such as by chemical dissolution. The encapsulation material 230 may be formed by any appropriate method to substantially encapsulate each of the conductive wire structures 220, with a portion of each of the first solder structures 242 exposed, as shown n FIG. 20. As shown in FIG. 21, the first solder layer 212 may be formed on the encapsulation material 230 and on the first solder structures 242 of each conductive wire structure 220. The structure of FIG. 21 may then be incorporated into the integrated circuit device assembly 100, as shown in FIG. 14.

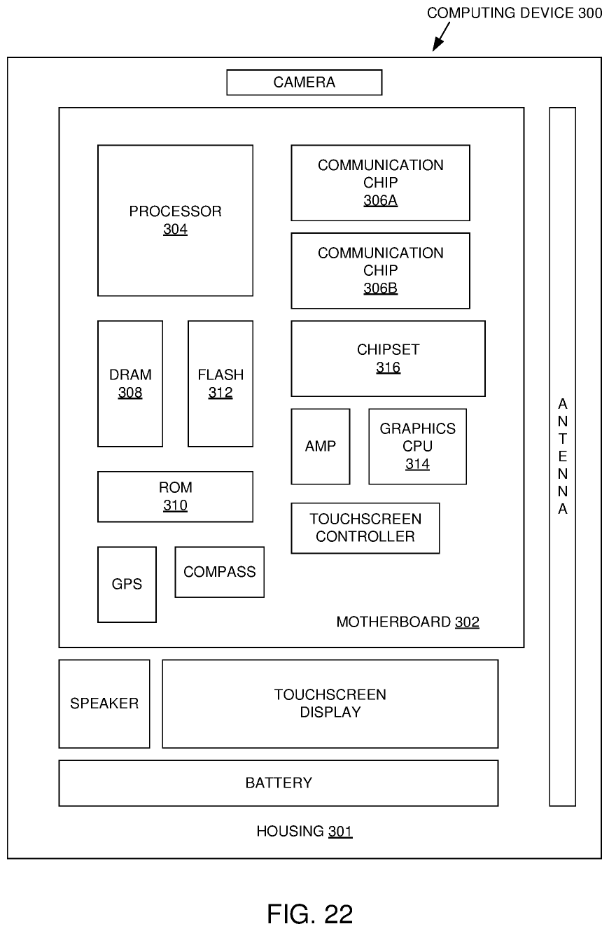

FIG. 22 illustrates an electronic or computing device 300 in accordance with one implementation of the present description. The computing device 300 may include a housing 301 having a board 302 disposed therein. The computing device 300 may include a number of integrated circuit components, including but not limited to a processor 304, at least one communication chip 306A, 306B, volatile memory 308 (e.g., DRAM), non-volatile memory 310 (e.g., ROM), flash memory 312, a graphics processor or CPU 314, a digital signal processor (not shown), a crypto processor (not shown), a chipset 316, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 302. In some implementations, at least one of the integrated circuit components may be a part of the processor 304.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the integrated circuit components may include an integrated circuit package comprising a heat dissipation device having a thermal contact surface; a thermal interface structure thermally connected to the thermal contact surface of the heat dissipation device, wherein the thermal interface structure comprises: at least one conductive wire structure comprising: a conductive wire having a first end; a first barrier layer adjacent the first end of the conductive wire; and a first solder structure adjacent the first barrier layer; an encapsulation material substantially encapsulating the at least one conductive wire structure; and a first solder layer abutting the encapsulation material and abutting the first solder structure; and an integrated circuit device, wherein the integrated circuit device is thermally connected to the thermal interface structure.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-22. The subject matter may be applied to other integrated circuit devices and assembly applications, as well as any appropriate electronic application, as will be understood to those skilled in the art.

The follow examples pertain to further embodiments and specifics in the examples may be used anywhere in one or more embodiments, wherein Example 1 is an apparatus comprising at least one conductive wire structure comprising a conductive wire having a first end, a first barrier layer adjacent the first end of the conductive wire, and a first solder structure adjacent the first barrier layer; an encapsulation material substantially encapsulating the at least one conductive wire structure; and a first solder layer abutting the encapsulation material and abutting the first solder structure.

In Example 2, the subject matter of Example 1 can optionally include the at least one conductive wire structure further comprising the conductive wire having a second end opposing the first end, a second barrier layer adjacent the second end of the conduct wire, and a second solder structure adjacent the second barrier layer, and further comprising a second solder layer abutting the encapsulation material and abutting the second solder structure.

In Example 3, the subject matter of any of Examples 1 to 2 can optionally include the conductive wire comprising copper.

In Example 4, the subject matter of any of Examples 1 to 3 can optionally include the first barrier layer comprising a nitride of a refractory metal.

In Example 5, the subject matter of any of Examples 1 to 4 can optionally include the first solder layer comprising indium.

Example 6 is an apparatus comprising a heat dissipation device having a thermal contact surface, a thermal interface structure thermally connected to the thermal contact surface of the heat dissipation device, wherein the thermal interface structure comprises at least one conductive wire structure comprising a conductive wire having a first end, a first barrier layer adjacent the first end of the conductive wire, and a first solder structure adjacent the first barrier layer; an encapsulation material substantially encapsulating the at least one conductive wire structure; and a first solder layer abutting the encapsulation material and abutting the first solder structure; and an integrated circuit device, wherein the integrated circuit device is thermally connected to the thermal interface structure.

In Example 7, the subject matter of Example 6 can optionally include the at least one conductive wire structure further comprising the conductive wire having a second end opposing the first end, a second barrier layer adjacent the second end of the conduct wire, and a second solder structure adjacent the second barrier layer, and further comprising a second solder layer abutting the encapsulation material and abutting the second solder structure, and abutting the thermal contact surface of the heat dissipation device; and wherein the first solder layer abuts the integrated circuit device.

In Example 8, the subject matter of Example 6 can optionally include the at least one conductive wire structure further comprising the conductive wire having a second end opposing the first end, abutting the thermal contact surface of the heat dissipation device, and wherein the first solder layer abuts the integrated circuit device.

In Example 9, the subject matter of any of Examples 6 to 8 can optionally include an electronic substrate; wherein the integrated circuit device has a first surface and an opposing second surface; wherein the first surface of the integrated circuit device is electrically attached to the electronic substrate; and wherein the second surface of the integrated circuit device abuts the first solder layer.

In Example 10, the subject matter of any of Examples 6 to 9 can optionally include the heat dissipation device being attached to the electronic substrate.

In Example 11, the subject matter of any of Examples 6 to 10 can optionally include the conductive wire comprising copper.

In Example 12, the subject matter of any of Examples 6 to 11 can optionally include the first barrier layer comprising a nitride of a refractory metal.

In Example 13, the subject matter of any of Examples 6 to 12 can optionally include the first solder layer comprising indium.

Example 14 is an electronic system, comprising a board and an integrated circuit package electrically attached to the board, wherein the integrated circuit package comprises an electronic substrate, an integrated circuit device having a first surface electrically attached to the electronic substrate, a heat dissipation device having a thermal contact surface, a thermal interface structure thermally connected to the thermal contact surface of the heat dissipation device, wherein the thermal interface structure comprises at least one conductive wire structure comprising a conductive wire having a first end, a first barrier layer adjacent the first end of the conductive wire, and a first solder structure adjacent the first barrier layer; an encapsulation material substantially encapsulating the at least one conductive wire structure; and a first solder layer abutting the encapsulation material and abutting the first solder structure; and an integrated circuit device, wherein the integrated circuit device is thermally connected to the thermal interface structure.

In Example 15, the subject matter of Example 14 can optionally include the at least one conductive wire structure further comprising the conductive wire having a second end opposing the first end, a second barrier layer adjacent the second end of the conduct wire, and a second solder structure adjacent the second barrier layer, and further comprising a second solder layer abutting the encapsulation material and abutting the second solder structure, and abutting the thermal contact surface of the heat dissipation device; and wherein the first solder layer abuts the integrated circuit device.

In Example 16, the subject matter of Example 14 can optionally include the at least one conductive wire structure further comprising the conductive wire having a second end opposing the first end, abutting the thermal contact surface of the heat dissipation device, and wherein the first solder layer abuts the integrated circuit device.

In Example 17, the subject matter of any of Examples 14 to 16 can optionally include an electronic substrate; wherein the integrated circuit device has a first surface and an opposing second surface; wherein the first surface of the integrated circuit device is electrically attached to the electronic substrate; and wherein the second surface of the integrated circuit device abuts the first solder layer.

In Example 18, the subject matter of any of Examples 14 to 17 can optionally include the heat dissipation device being attached to the electronic substrate.

In Example 19, the subject matter of any of Examples 14 to 18 can optionally include the conductive wire comprising copper.

In Example 20, the subject matter of any of Examples 14 to 19 can optionally include the first barrier layer comprising a nitride of a refractory metal.

In Example 21, the subject matter of any of Examples 14 to 20 can optionally include the first solder layer comprising indium.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An apparatus comprising:
at least one conductive wire structure, wherein the at least one conductive wire comprises:
a conductive wire having a first end;
a first barrier layer adjacent the first end of the conductive wire; and
a first solder structure adjacent the first barrier layer;
an encapsulation material substantially encapsulating the at least one conductive wire structure; and
a first solder layer abutting the encapsulation material and abutting the first solder structure.

2. The apparatus of claim 1, wherein the at least one conductive wire structure further comprises the conductive wire having a second end opposing the first end, a second barrier layer adjacent the second end of the conduct wire, and a second solder structure adjacent the second barrier layer; and further comprising a second solder layer abutting the encapsulation material and abutting the second solder structure.

3. The apparatus of claim 1, wherein the conductive wire comprises copper.

4. The apparatus of claim 1, wherein the first barrier layer comprises a nitride of a refractory metal.

5. The apparatus of claim 1, wherein the first solder layer comprises indium.

6. An apparatus comprising:
a heat dissipation device having a thermal contact surface;
a thermal interface structure thermally connected to the thermal contact surface of the heat dissipation device, wherein the thermal interface structure comprises:
at least one conductive wire structure, comprising:
a conductive wire having a first end;
a first barrier layer adjacent the first end of the conductive wire; and
a first solder structure adjacent the first barrier layer;
an encapsulation material substantially encapsulating the at least one conductive wire structure; and
a first solder layer abutting the encapsulation material and abutting the first solder structure; and
an integrated circuit device, wherein the integrated circuit device is thermally connected to the thermal interface structure.

7. The apparatus of claim 6, wherein the at least one conductive wire structure further comprises the conductive wire having a second end opposing the first end, a second barrier layer adjacent the second end of the conduct wire, and a second solder structure adjacent the second barrier layer; further comprising a second solder layer abutting the encapsulation material, abutting the second solder structure, and abutting the thermal contact surface of the heat dissipation device; and wherein the first solder layer abuts the integrated circuit device.

8. The apparatus of claim 6, wherein the at least one conductive wire structure further comprises the conductive wire having a second end, opposing the first end, abutting the thermal contact surface of the heat dissipation device; and wherein the first solder layer abuts the integrated circuit device.

9. The apparatus of claim 6, further comprises an electronic substrate; wherein the integrated circuit device has a first surface and an opposing second surface; wherein the first surface of the integrated circuit device is electrically attached to the electronic substrate; and wherein the second surface of the integrated circuit device abuts the first solder layer.

10. The apparatus of claim 9, wherein the heat dissipation device is attached to the electronic substrate.

11. The apparatus of claim 6, wherein the conductive wire comprises copper.

12. The apparatus of claim 6, wherein the first barrier layer comprises a nitride of a refractory metal.

13. The apparatus of claim 6, wherein the first solder layer comprises indium.

14. An electronic system, comprising:
a board;
an integrated circuit package electrically attached to the board, wherein the integrated circuit package comprises:
an electronic substrate;
an integrated circuit device having a first surface electrically attached to the electronic substrate;
a heat dissipation device having a thermal contact surface;
a thermal interface structure thermally connected to the thermal contact surface of the heat dissipation device, wherein the thermal interface structure comprises:
at least one conductive wire structure, comprising:
a conductive wire having a first end;
a first barrier layer adjacent the first end of the conductive wire; and
a first solder structure adjacent the first barrier layer;
an encapsulation material substantially encapsulating the at least one conductive wire structure; and
a first solder layer abutting the encapsulation material and abutting the first solder structure; and
wherein the integrated circuit device is thermally connected to the thermal interface structure.

15. The apparatus of claim 14, wherein the at least one conductive wire structure further comprises the conductive wire having a second end opposing the first end, a second barrier layer adjacent the second end of the conduct wire, and a second solder structure adjacent the second barrier layer; further comprising a second solder layer abutting the encapsulation material, abutting the second solder structure, and abutting the thermal contact surface of the heat dissipation device; and wherein the first solder layer abuts the integrated circuit device.

16. The apparatus of claim 14, wherein the at least one conductive wire structure further comprises the conductive wire having a second end, opposing the first end, abutting the thermal contact surface of the heat dissipation device; and wherein the first solder layer abuts the integrated circuit device.

17. The apparatus of claim 14, further comprises an electronic substrate; wherein the integrated circuit device has a first surface and an opposing second surface; wherein the first surface of the integrated circuit device is electrically attached to the electronic substrate; and wherein the second surface of the integrated circuit device abuts the first solder layer.

18. The apparatus of claim 17, wherein the heat dissipation device is attached to the electronic substrate.

19. The apparatus of claim 14, wherein the conductive wire comprises copper.

20. The apparatus of claim 14, wherein the first barrier layer comprises a nitride of a refractory metal.
